(19) United States
(12) Patent Application Publication
(10) Pub. No.: US 2023/0064066 A1
(43) Pub. Date: Mar. 2, 2023

(54) WAFER-LEVEL BACKSIDE LAYER FOR SEMICONDUCTOR APPARATUS

(71) Applicant: TEXAS INSTRUMENTS INCORPORATED, Dallas, TX (US)

(72) Inventors: HAO ZHANG, CHENGDU (CN); YUNTAO XU, CHENGDU (CN); MINHUI MA, CHENGDU (CN); YUAN ZHANG, LESHAN (CN); DING HAN, CHENGDU (CN)

(21) Appl. No.: 17/459,869

(22) Filed: Aug. 27, 2021

(51) Int. Cl. H01L 21/683; H01L 21/78

(52) U.S. Cl. CPC H01L 21/6836; H01L 21/78; H01L 2221/68327

(57) ABSTRACT

In a described example, a method of forming a semiconductor apparatus includes applying a layer of an electrically insulating material on a backside of a semiconductor wafer having a plurality of integrated circuit dice. The method also includes mounting the wafer to dicing tape with a die attach film, in which the die attach film is between the backside layer and the dicing tape, and cutting the wafer into respective dice.

### TECHNICAL FIELD

This description relates to semiconductor apparatuses having a wafer-level backside layer.

### BACKGROUND

Die preparation is a part of the semiconductor device fabrication process in which a wafer is prepared for IC packaging and testing. The process of die preparation generally includes wafer mounting and wafer dicing. During wafer mounting, the wafer is mounted on a tape (e.g., dicing tape). Wafer dicing is used to separate individual die from a wafer of semiconductor, while mounted to the dicing tape. The dicing process can involve scribing and breaking, mechanical sawing or laser cutting. Once a wafer has been diced, the die will stay on the dicing tape until they are extracted by die-handling equipment, such as a die bonder or die sorter, later in the electronics assembly process.

### SUMMARY

In a described example, a method of forming a semiconductor apparatus includes applying a layer of an electrically insulating material on a backside of a semiconductor wafer having a plurality of integrated circuit dice. The method also includes mounting the wafer to dicing tape with a die attach film, in which the die attach film is between the backside layer and the dicing tape, and cutting the wafer into respective dice.

In a further described example, the method of forming a semiconductor apparatus includes attaching a given die to a substrate and encapsulating the given die and substrate within a packaging material to provide a packaged semiconductor apparatus.

In another described example, a semiconductor apparatus includes a semiconductor die including an integrated circuit. A backside layer of an electrically insulating and high modulus material is on a backside of the die. The semiconductor apparatus also includes a die attach layer, in which the backside layer is located between the backside of the die and the die attach layer.

### BRIEF DESCRIPTION OF THE DRAWINGS

FIG. 1 is a flow diagram depicting an example die separation method that can be used to form semiconductor apparatus.

FIGS. 2-6 are cross-sectional views of a semiconductor apparatus being formed according to the method of FIG. 1.

FIG. 7 depicts an example of screen printing being used to form a backside layer on a wafer.

FIGS. 8A-8B depict an example of spin coating being used to form a backside layer on a wafer.

FIG. 9 depicts an example of spray coating being used to form a backside layer on a wafer.

FIGS. 10A-10B depict an example of applying a film coating to a backside of a wafer.

FIG. 11 depicts an example of a packaged semiconductor apparatus.

### DETAILED DESCRIPTION

Example embodiments relate to methods of fabricating semiconductor apparatuses and to semiconductor apparatuses.

As an example, a method includes forming one or more backside layers of an electrically insulating material on a backside of a semiconductor wafer. At this stage, when the electrically insulating material is applied, a plurality of integrated circuit (IC) dice have been formed on the wafer according to respective fabrication processing steps. For example, each of the IC dice on the wafer can contain any combination of active and passive devices, such as CMOS, BiCMOS and bipolar junction transistors—as well as capacitors, optoelectronic devices, inductors, resistors, and diodes. The assembly including the wafer and backside layer can be mounted to a dicing tape with a die attach film, such that the die attach film is located between the backside layer and the dicing tape. The wafer can then be cut into respective dice, such as by a mechanical saw or other cutting mechanism. After cutting the wafer into respective dice, subsequent fabrication can be performed, such as a die attach operation and wire bonding with respect to leadframe or other structure. The resulting IC chip can be packaged in an IC packaging material such as plastic or ceramic.

In an example, the backside layer has a sufficiently high young's modulus to provide a hard barrier to resist embedding debris into the backside layer. The approach described herein enables the mechanical process to be utilized for the wafer and die preparation. The hard electrically insulating backside layer also reduces the amount of fragments of the die attach film that can be moved into the wafer. Accordingly, resulting electrical interference that can arise from such spurious fragments is also reduced. Therefore, by implementing wafer and die preparation, as described herein, additional processing steps currently used to mitigate such fragments can be omitted, which can reduce the overall costs compared to existing die preparation methods. Additionally, the approach described herein does not require wafer expansion after cutting such that the risk of DAF not separating into blocks is reduced compared to approaches that implement such wafer expansion where there is an increased risk of DAF un-separation.

As used herein, the term semiconductor apparatus (and its variants) refers to any structure or device that includes a semiconductor substrate. For example, a semiconductor substrate (e.g., a wafer) having one or more (e.g., a plurality of) integrated circuit (IC) dice is a semiconductor apparatus. A die, which may be on a wafer or separated from the wafer, is another example of a semiconductor apparatus. Additionally, one or more dice that have been packaged in packaging material is yet another example of a semiconductor apparatus. Thus, a semiconductor apparatus can exist at any stage of the semiconductor fabrication workflow including the resulting IC chip.

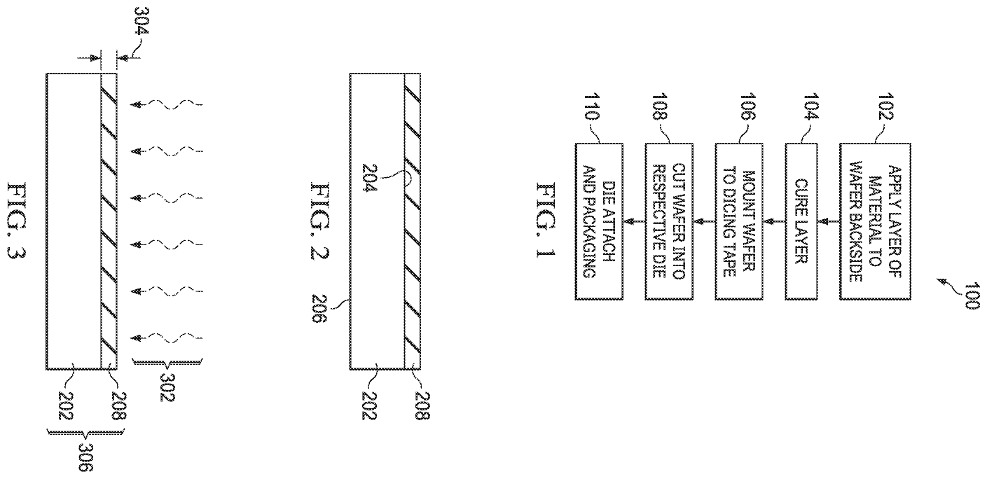

FIG. 1 is a flow diagram depicting an example method 100 that can be implemented to perform die preparation in an overall semiconductor fabrication workflow. The method 100 is described in relation to the cross-sectional views of FIGS. 2-6, which show an example processing progression of wafer preparation that can be used in a semiconductor fabrication workflow to form a semiconductor apparatus.

At 102, one or more layers of electrically insulating material are formed on the backside of a semiconductor wafer. As described herein, the wafer is a post fabrication wafer that includes a plurality of IC dice formed on the wafer. For example, as shown in FIG. 2, the wafer 202 includes a backside 204 and a front side surface 206. The front side 206 can include leads for circuitry formed on each of the respective dice, which leads are be coupled to IC terminals through bond wires or other types of connections. The layer of electrically insulating material 208 is applied to the backside surface 204 of the wafer 202. For example, the material that forms the layer 208 can be applied to the backside 204 of the wafer 202 in the form of a liquid, paste, film or coating. Depending on the viscosity of the material when applied and desired thickness, the material can be applied by a screen or stencil print process, a spin coating process, a spray coating process or applied as a wafer backside coating, such as a laminated film.

At 104, the backside layer is cured. For example, as shown in FIG. 3, radiation or heat, shown schematically at 302, is applied to cure the backside layer 208. The curing at 104 hardens the layer 208. The cured layer 208 thus has a high young's modulus to provide a hardened layer between the backside of the wafer and a die attach film (on a surface of dicing tape used at 106). As used herein in relation to the layer 208, a high modulus refers to a material having a Young's modulus greater than approximately 1 GPa at room temperature. Thus, the cured layer 208 can be referred to as a high modulus layer. The high modulus layer 208 also maintains its electrically insulating properties.

The type of process to perform the curing 302 (at 104 in the method 100) can depend on the type of material used to form the layer 208. In an example, the backside layer 208 can be cured to a sufficient hardness by placing the wafer assembly 306 (or a plurality of such wafer assemblies) in an oven for heating (e.g., at temperatures from about 90° C. to about 250° C.). In another example, the material can be implemented as an epoxy or other resin material that can be cured through an ultraviolet (UV) curing process to harden the layer 208 to a sufficiently high young's modulus on the wafer backside 204. The resulting high modulus layer 208 can have a thickness 304 that is less than approximately 100 micrometers.

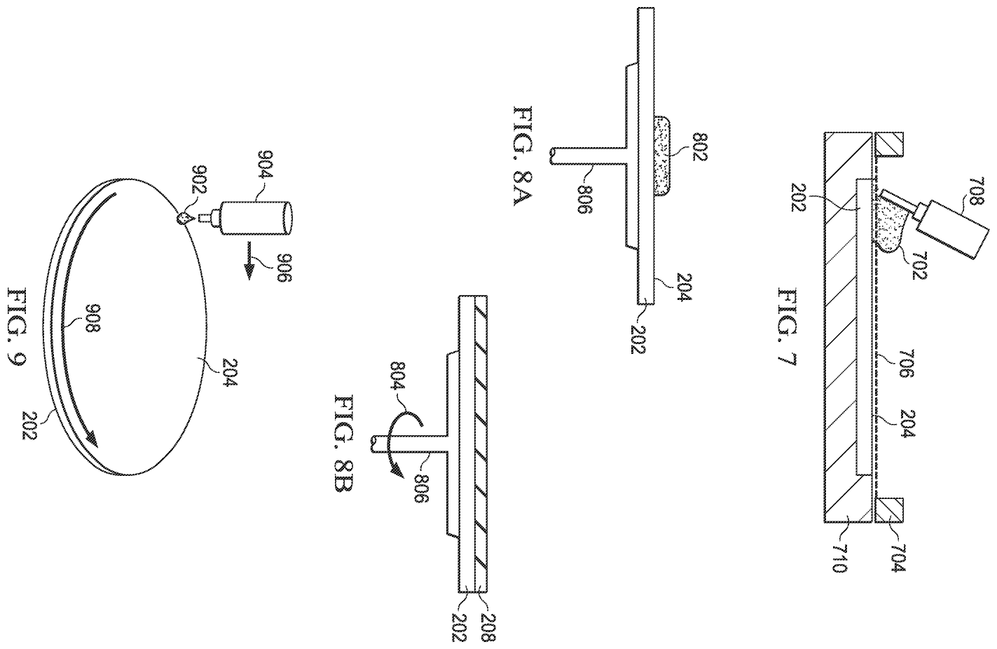

FIGS. 7-10B depict examples of different processes that can be utilized to apply the high modulus layer 208 to the wafer backside 204. As described above, the material can be applied with a different viscosity (e.g., a liquid, paste or film) depending on the process that is utilized to apply the material.

In the example of FIG. 7, the high modulus layer 208 can be applied through a screen or stencil print process. For example, a volume of electrically insulating material 702, which can be in the form of a liquid or paste, can be applied onto a screen mesh 706 within a stencil frame 704. A squeegee or other applicator device 708 can dispense the material 702, such as by pressing and/or pushing the material along and through the screen 706 and onto the backside 204 of the wafer 202. For example, the wafer 202 can be held in place during application of the material by a vacuum pallet 710. In an example, the material 702 can be applied as a paste onto the backside 204 of the wafer 202. The pressure, the thickness of the mesh 706, and corresponding design and speed of the squeegee can all depend on the mechanical properties of the material 702 being applied. After being applied, the material 702 can be cured into the high modulus layer 208 as described herein.

In the examples of 8A and 8B, a spin coating process is used to deposit a uniform layer of the electrically insulating material onto the backside 204 of the wafer 202. For example, a volume of material 802 is applied near a center of the wafer backside 204 and the wafer substrate 202 is rotated (as shown by arrow 804 in FIG. 8B) to spread the layer by centrifugal force. For example, a spin coater (spinner) 806 supports the wafer 202 as the material 802 is applied to the wafer 202. The rotation can continue while a portion of the material spins off the edges of the wafer 202. After being applied, the material 802 can be cured into the high modulus layer 208 as described herein. The resulting thickness of the layer 208 will depend on the viscosity of the material 802.

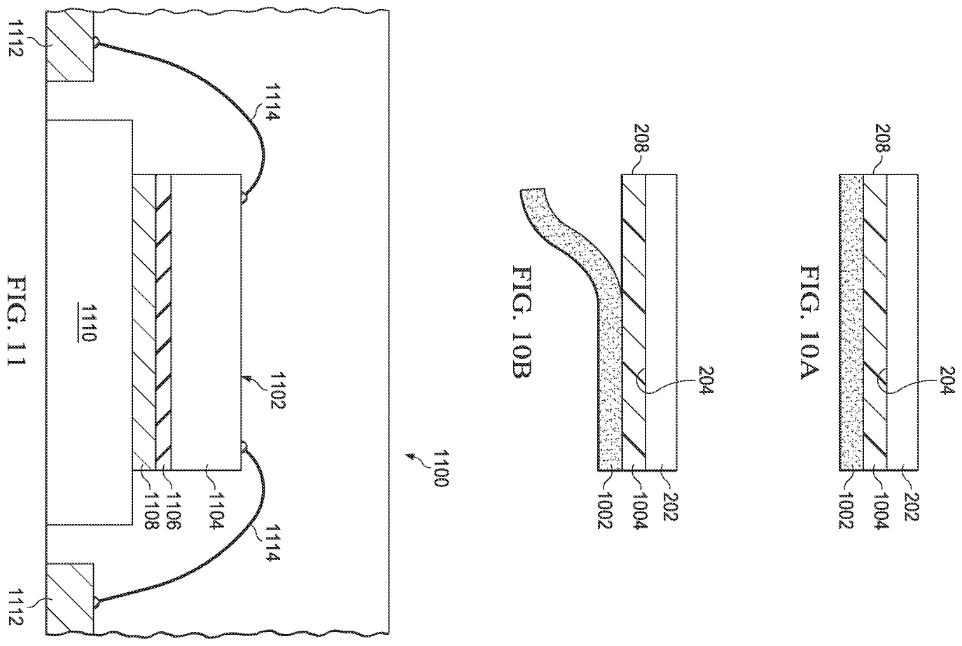

FIG. 9 depict an example of a spray coating process in which a liquid material 902 is sprayed onto the backside 204 of the wafer 202 from a nozzle 904. During application onto the backside of the wafer 202, the spray nozzle 904 may be moved in the direction of arrow 906 while the wafer is rotated in a direction shown by arrow 908. The combination of movement of the sprayer 904 and rotation of the wafer 202 ensures that the material is applied to the entire backside 204 of the wafer. After being applied, the material 902 can be cured into the high modulus layer 208 as described herein.

FIGS. 10A and 10B illustrate an example in which a coating material 1004 is applied to the backside 204 of the wafer 202 for forming the high modulus layer 208. In the example of FIGS. 10A and 10B, the coating material 1004 is applied in the form of a lamination that includes a supporting tape layer 1002 and a layer of the coating material 1004. After being applied, the supporting tape layer 1002 can be removed from the layer 1004, such as shown in FIG. 10B. The thickness of the film layer 1004 can range from about 3 micrometers to about 100 micrometers. Additionally, the film material layer 1004 can be cured into the high modulus layer 208 as described herein.

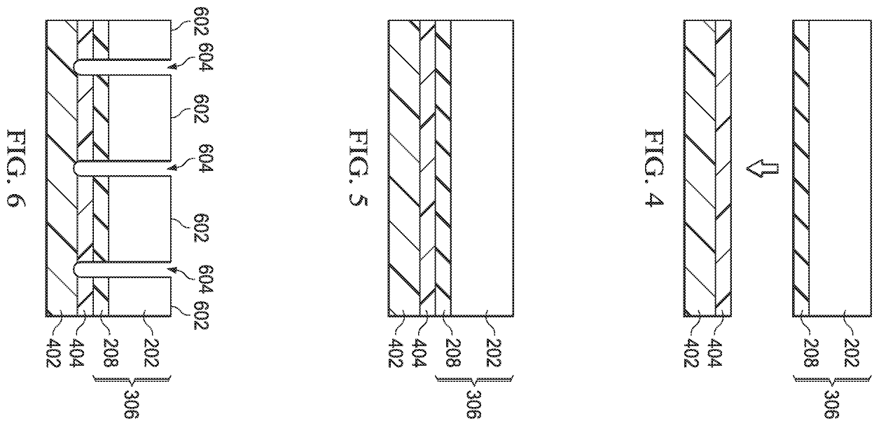

Referring back to FIG. 1, at 106, the wafer, including the applied backside layer, is mounted to dicing tape. For example, in FIGS. 3 and 4, the wafer assembly 306 is shown being mounted to dicing tape 402. In the example of FIGS. 4 and 5, the dicing tape 402 is an integrated tape structure that includes a die attach film (DAF) layer 404 (e.g., a 2-in-1 dicing tape). In another example, the DAF layer can be applied to the dicing tape. The DAF layer 404 is implemented as one or more layers that includes top layer of an adhesive material configured to attach the wafer to the dicing tape 402 to facilitate singulation. As shown in FIG. 5, when the wafer assembly 306 is mounted to the dicing tape 402, the DAF layer 404 resides between the high modulus layer 208 and the dicing tape 402. As a result, a multilayer wafer structure is formed which includes the wafer 202, high modulus layer 208, DAF layer 404, and dicing tape 402. The wafer mounting 106 can be implemented according to existing wafer mount processes. The DAF layer 404 thus is an adhesive film configured to bond to the exposed surface of the high modulus layer 208.

At 108 the wafer is cut into respective dice in a singulation process. The semiconductor dice on the wafer 202 are spaced apart from each other by zones of unprocessed semiconductor material, which can be referred to as “saw streets” because they form a grid between respective semiconductor dice on the wafer. For example, the width of the saw street 604 can be small such as 100 μm or less. As shown in FIG. 6, the wafer cutting 108 can be implemented using a mechanical wafer saw to cut the wafer 202 into dice 602 having a rectangular or other shape. As a result, the saw streets are largely destroyed during the singulation process at 108. The dice 602, collectively or individually, are semiconductor apparatuses.

The use of the high modulus layer 208 enables mechanical sawing process to be implemented for a greater range of semiconductor fabrication workflows. For example, in the absence of the high modulus layer, as in some existing fabrication processes, use of a mechanical saw for cutting dice can induce silicon debris, which tends to embed into the DAF layer. If such silicon debris embeds into the DAF layer 404 electrical leakage can occur in the resulting packaged semiconductor apparatuses. As described herein, the use of the high modulus layer 208 can reduce or eliminate semiconductor (e.g., silicon) debris from embedding in the DAF layer 404 during cutting with a mechanical saw. As result, the method 100 can likewise reduce electrical leakage in the semiconductor apparatus when a mechanical saw is utilized for wafer cutting. Mechanical sawing is especially useful because laser dicing is not suitable for all fabrication processes. For example, laser dicing cannot be applied effectively where there is excessive wafer warpage.

As shown in the example of FIG. 6, the cutting (at 108) can be implemented as a full (e.g., 100%) cut through the wafer 202, the high modulus layer 208 and the DAF layer 404. In this way, after cutting at 108, the respective dice 602 are held together only by the dicing tape 402. Because a full cut process can be utilized, the approach described herein further can be implemented without requiring any wafer expansion process to further separate the dice 602 from each other. Because the method 100 described herein can be implemented in the absence of wafer expansion, the risk of DAF un-separation is reduced. Additionally, because wafer expansion is not needed, the overall process can be implemented at lower cost compared to existing approaches that require wafer expansion processes. That is, no wafer expander apparatus is needed and an expansion process can be omitted from the overall fabrication workflow. In other examples, a smaller percentage of cut through (e.g., from 50% to about 90%) can be implemented by mechanical sawing or another cutting technology, but some expansion may be needed to separate dice 602.

At 110, the method 100 includes attaching the die to a substrate to form a die assembly, and packaging the die assembly in a suitable packaging material. The substrate can include a leadframe or other support structure (e.g., head pad) of the package. In an example, respective die can be picked from the dicing tape 402 and physically attached to the substrate using the die attach layer and/or another adhesive (e.g., an epoxy adhesive or solder). The die can thus be attached to the substrate by a chip bonding technique, such as epoxy attach, eutectic solder attach, or glass frit attach. In some examples, wire bonding can be utilized to connect leads on the die surface to respective terminals of the leadframe. The packaging material can be any suitable IC chip packaging material such as a plastic material or ceramic material to provide a packaged IC die.

FIG. 11 is a side sectional view of packaged electrical device 1100 that can be formed according to the method 100. The packaged electrical device 1100 may configured according to any type of package structure, including as Quad Flat No-Lead (QFN), Dual Flat No-Lead (DFN), or Small Outline-Transistor (SOT). In other examples, the semiconductor die 602 may have other configurations for use in other packaging technologies. Thus, the die 602 that is formed in the method 100 can be configured for use according to the packaging technology that is being used.

In the following example, the packaged electrical device 1100 is described as implemented as a QFN structure. The packaged electrical device 1100 includes an IC die 1102, such as corresponding to the die 602 of FIG. 6 produced according to the method 100. Thus, the die 1102 includes a semiconductor wafer 1104, a high modulus layer 1106, and a die attach layer 1108. The die attach layer 1108 can be configured to couple to a pad 1110 or other substrate. For example, the pad 1110 can be an exposed thermal pad of the respective leadframe 1112. In other examples, the die can be configured to sit on a lead rather than a thermal pad. Also shown in the example of FIG. 11 are respective wire bonds 1114 configured to electrically couple leads on the IC die 1102 to respective lead terminals or posts of the leadframe 1112. In some examples, an additional adhesive can be used in addition to the die attach layer 1108, such as an electrically conductively adhesive or solder for attaching the die 1102 to the pad 1110.

In view of the foregoing, methods and the semiconductor apparatuses can be provided with improved performance and at lower cost compared to existing approaches. For example, the methods and apparatuses described herein enable a mechanical sawing process to be used with a DAF laminated wafer for a broad range of devices and fabrication processes. The methods described herein can also provide lower cost process. For example, a lower cost dicing tape (e.g., having a thinner DAF layer) can be used in the methods described herein to achieve equal or better performance compared to some existing approaches that require higher performance dicing tape. In further examples, the methods described herein can be implemented without a wafer expansion process and/or use of a wafer expander, such that is little or no risk of DAF un-separation.

In this application, the term “couple” or “couples” means either an indirect or direct connection. Thus, if a first device couples to a second device, that connection may be through a direct connection or through an indirect connection via other devices and connections. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A.

The recitation “based on” means “based at least in part on.” Therefore, if X is based on Y, X may be a function of Y and any number of other factors.

Modifications are possible in the described embodiments, and other embodiments are possible, within the scope of the claims.

What is claimed is:

1. A method of forming a semiconductor apparatus, comprising:
forming a backside layer of an electrically insulating material on a backside of a semiconductor wafer having a plurality of integrated circuit dice;
mounting the wafer to dicing tape with a die attach film in which the die attach film is between the backside layer and the dicing tape; and
cutting the wafer into respective dice.

2. The method of claim 1, further comprising:
curing the backside layer that is applied to the backside of the wafer.

3. The method of claim 2, wherein the cured backside layer has a Young's Modulus greater than approximately 1 GPa.

4. The method of claim 1, wherein cutting the wafer comprises wafer sawing.

5. The method of claim 1, wherein cutting the wafer comprises cutting fully through the wafer, the backside layer and the die attach film to expose the dicing tape in scribe lines formed by the cutting.

6. The method of claim 1, wherein forming the backside layer comprises applying a single layer of the electrically insulating material on the backside of the wafer.

7. The method of claim 1, wherein forming the backside layer comprises screen printing the electrically insulating layer on the backside of the wafer.

8. The method of claim 1, wherein the backside layer has a thickness less than 100 μm.

9. The method of claim 1, further comprising:
attaching the respective dice to a substrate; and
encapsulating the die and the substrate within a packaging material to provide a packaged semiconductor apparatus.

10. The method of claim 9, wherein the substrate comprises a leadframe or a pad.

11. The method of claim 1, wherein no tape expansion is performed after cutting the wafer.

12. A semiconductor apparatus, comprising:
a semiconductor die including an integrated circuit;
a backside layer of an electrically insulating material on a backside of the die; and
a die attach layer, the backside layer located between the backside of the die and the die attach layer.

13. The semiconductor apparatus of claim 12, wherein the backside layer has a Young's Modulus greater than approximately 1 GPa.

14. The semiconductor apparatus of claim 12, wherein the backside layer comprises a single layer of the electrically insulating material on the backside of the wafer.

15. The semiconductor apparatus of claim 12, wherein the backside layer has a thickness less than 100 μm.

16. The semiconductor apparatus of claim 12, further comprising:
a substrate, the die mounted to the substrate; and
a packaging material encapsulating the die and the substrate.

17. A method of forming a semiconductor apparatus, comprising:
applying a backside layer of an electrically insulating and high modulus material on a backside of a semiconductor wafer having a plurality of integrated circuit dice;
mounting the wafer to dicing tape with a die attach film in which the die attach film is between the backside layer and the dicing tape;
cutting the wafer into respective dice;
attaching a given die to a substrate; and
encapsulating the die and the substrate within a packaging material to provide a packaged semiconductor apparatus.

18. The method of claim 17, further comprising:
curing the backside layer that is applied to the backside of the wafer prior to the mounting.

19. The method of claim 18, wherein the cured backside layer has a Young's Modulus greater than approximately 1 GPa.

20. The method of claim 18, wherein cutting the wafer comprises cutting fully through the wafer, the backside layer and the die attach film to expose the dicing tape in scribe lines formed by the cutting.

21. The method of claim 17, wherein the packaged semiconductor device comprises a quad flat no-lead (QFN) package.
